(19) United States
(12) Patent Application Publication
(10) Pub. No.: US 2015/0236692 A1
(43) Pub. Date: Aug. 20, 2015

(54) DRIVING SIGNAL GENERATING CIRCUIT AND POWER SEMICONDUCTOR DEVICE DRIVING APPARATUS INCLUDING THE SAME

(71) Applicant: Samsung Electro-Mechanics Co., Ltd., Suwon-Si (KR)

(72) Inventor: Chang Jae HEO, Suwon-Si (KR)

(73) Assignee: SAMSUNG ELECTRO-MECHANICS CO., LTD., Suwon-Si (KR)

(21) Appl. No.: 14/269,065

(22) Filed: May 2, 2014

(30) Foreign Application Priority Data
Feb. 17, 2014 (KR) 10-2014-0017780

(51) Int. Cl. H03K 17/687

(52) U.S. Cl. CPC H03K 17/687

(57) ABSTRACT

There are provided a driving signal generating circuit and a power semiconductor device driving apparatus including the same. The driving signal generating circuit for generating driving signals provided to first and second transistors driving a power semiconductor device includes: a first driving signal generating unit generating a first driving signal including a high level signal and a low level signal and providing the first driving signal to a gate of the first transistor; a detecting unit detecting a detection voltage depending on a current flowing in the power semiconductor device; a second driving signal generating unit generating a second driving signal in inverse proportion to the detection voltage; and a switching unit performing a switching operation depending on the first driving signal to transfer the second driving signal to a gate of the second transistor.

### CROSS-REFERENCE TO RELATED APPLICATION

This application claims the benefit of Korean Patent Application No. 10-2014-0017780 filed on Feb. 17, 2014, with the Korean Intellectual Property Office, the disclosure of which is incorporated herein by reference.

### BACKGROUND

The present disclosure relates to a driving signal generating circuit and a power semiconductor device driving apparatus including the same.

A power semiconductor device such as an insulated gate bipolar transistor (IGBT) mainly drives a load having an inductance component, such as a motor. In the case in which the power semiconductor device is turned off, current flowing in the power semiconductor device instantaneously drops to a level of zero. When the current flowing in the power semiconductor device is changed to the zero level for a short time, electromotive force is instantaneously generated by the load having the inductance component, non-problematic in the case in which a level of the current flowing in the power semiconductor device is low. However, a problem in which the power semiconductor device is broken may occur in the case in which the level of the current flowing in the power semiconductor device is high.

The following Related Art Document (Patent Document 1), related to an inverter controlling apparatus, discloses that a soft turn-off time of an IGBT is maintained for an elongated period by delaying a forced turn-off control current of the IGBT, but does not disclose that a level of a driving signal is controlled to be in inverse proportion to a level of a current flowing in a power semiconductor device.

### RELATED ART DOCUMENT

(Patent Document 1) Korean Patent Laid-Opened Publication No. 10-2012-0029915

### SUMMARY

An aspect of the present disclosure may provide a driving signal generating circuit capable of controlling a level of a driving signal to be in inverse proportion to a level of a current flowing in a power semiconductor device, and a power semiconductor device driving apparatus including the same.

According to an aspect of the present disclosure, a driving signal generating circuit for generating driving signals provided to first and second transistors driving a power semiconductor device may include: a first driving signal generating unit generating a first driving signal including a high level signal and a low level signal and providing the first driving signal to a gate of the first transistor; a detecting unit detecting a detection voltage depending on a current flowing in the power semiconductor device; a second driving signal generating unit generating a second driving signal in inverse proportion to the detection voltage; and a switching unit performing a switching operation depending on the first driving signal to transfer the second driving signal to a gate of the second transistor.

The detecting unit may include a detection resistor disposed between the power semiconductor device and a ground.

The second driving signal generating unit may include: a first operational amplifier having an inverting terminal, a non-inverting terminal to which the detection voltage is applied, and an output terminal connected to the inverting terminal; a first resistor having one end connected to the output terminal of the first operational amplifier; a second operational amplifier having a non-inverting terminal to which a predetermined reference voltage is applied, an inverting terminal connected to the other end of the first resistor, and an output terminal outputting the second driving signal; and a second resistor disposed between the inverting terminal of the second operational amplifier and the output terminal of the second operational amplifier.

The switching unit may include: an inverter inverting the first driving signal; and a switch performing a switching operation through an output signal of the inverter and disposed between the second driving signal generating unit and a ground.

The switching unit may include a switch disposed between the second driving signal generating unit and the gate of the second transistor.

According to another aspect of the present disclosure, a power semiconductor device driving apparatus may include: a driving circuit including a first transistor driven so as to turn on a power semiconductor device and a second transistor driven so as to turn off the power semiconductor device; and a driving signal generating circuit generating a first driving signal driving the first transistor and a second driving signal driving the second transistor, wherein a level of the second driving signal is in inverse proportion to that of a current flowing in the power semiconductor device.

The first transistor may be disposed between a predetermined driving voltage terminal and a gate of the power semiconductor device, and the second transistor may be disposed between a ground and the gate of the power semiconductor device.

The first transistor may be a P-type transistor, and the second transistor may be an N-type transistor.

The driving signal generating circuit may include: a first driving signal generating unit generating the first driving signal including a high level signal and a low level signal; a detecting unit detecting a detection voltage depending on the current flowing in the power semiconductor device; a second driving signal generating unit generating the second driving signal in inverse proportion to the detection voltage; and a switching unit performing a switching operation depending on the first driving signal to transfer the second driving signal to a gate of the second transistor.

The detecting unit may include a detection resistor disposed between the power semiconductor device and a ground.

The second driving signal generating unit may include: a first operational amplifier having an inverting terminal, a non-inverting terminal to which the detection voltage is applied, and an output terminal connected to the inverting terminal; a first resistor having one end connected to the output terminal of the first operational amplifier; a second operational amplifier having a non-inverting terminal to which a predetermined reference voltage is applied, an inverting terminal connected to the other end of the first resistor, and an output terminal outputting the second driving signal; and a second resistor disposed between the inverting terminal of the second operational amplifier and the output terminal of the second operational amplifier.

The switching unit may include: an inverter inverting the first driving signal; and a switch performing a switching operation through an output signal of the inverter.

The switching unit may include a switch disposed between the second driving signal generating unit and the gate of the second transistor.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a block diagram illustrating a power semiconductor device driving apparatus according to an exemplary embodiment of the present disclosure;

FIG. 2 is a diagram illustrating a driving circuit according to an exemplary embodiment of the present disclosure;

FIG. 3 is a bock diagram illustrating a driving signal generating circuit according to an exemplary embodiment of the present disclosure;

FIGS. 4 and 5 are diagrams illustrating driving signal generating circuits according to various exemplary embodiments of the present disclosure; and

FIG. 6 is a graph illustrating current-voltage characteristics of an N-channel field effect transistor.

### DETAILED DESCRIPTION

Hereinafter, embodiments of the present disclosure will be described in detail with reference to the accompanying drawings. The disclosure may, however, be embodied in many different forms and should not be construed as being limited to the embodiments set forth herein. Rather, these embodiments are provided so that this disclosure will be thorough and complete, and will fully convey the scope of the disclosure to those skilled in the art. Throughout the drawings, the same or like reference numerals will be used to designate the same or like elements.

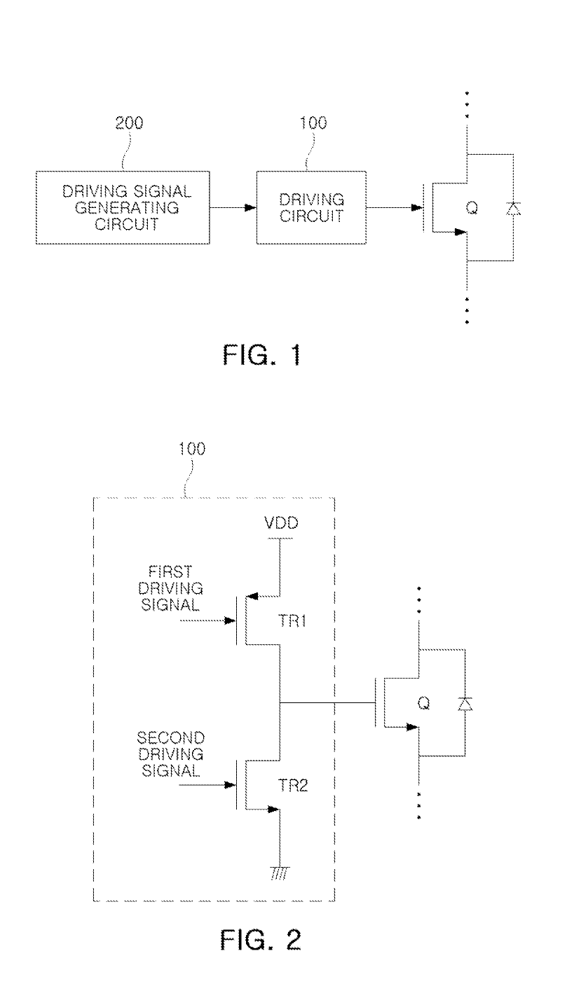

FIG. 1 is a block diagram illustrating a power semiconductor device driving apparatus according to an exemplary embodiment of the present disclosure.

Referring to FIG. 1, a power semiconductor device driving apparatus according to the present exemplary embodiment may include a driving circuit 100 and a driving signal generating circuit 200. The driving circuit 100 may include at least two transistors performing switching operations by first and second driving signals generated by the driving signal generating circuit 200, respectively, to turn on or turn off a power semiconductor device.

The driving signal generating circuit 200 may generate the first driving signal including a high level signal and a low level signal depending on a control signal input from the outside and generate the second driving signal in inverse proportion to a voltage depending on a current flowing in the power semiconductor device.

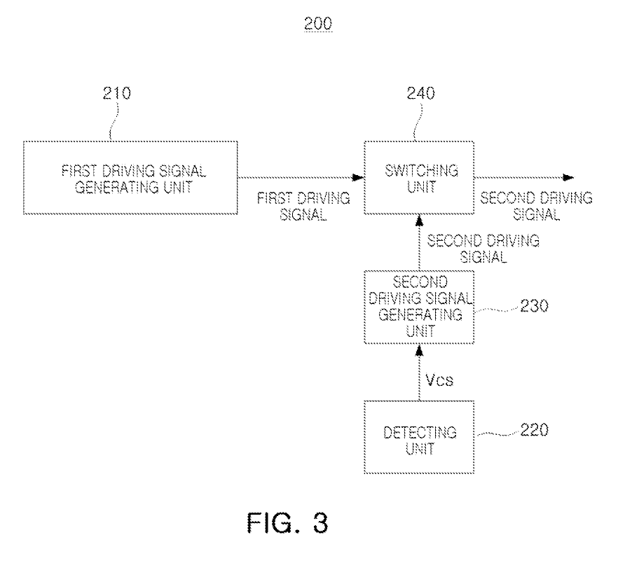

FIG. 2 is a diagram illustrating a driving circuit according to an exemplary embodiment of the present disclosure.

The driving circuit 100 may include at least two transistors TR1 and TR2, wherein the first transistor TR1 may be a P-type transistor including a P-channel field effect transistor and a PNP bipolar junction transistor, and the second transistor TR2 may be an N-type transistor including an N-channel field effect transistor and an NPN bipolar junction transistor.

For example, in the case in which each of the first and second transistors is implemented by a field effect transistor, the first transistor may have a source connected to a driving voltage VDD terminal, a gate having a first driving signal applied thereto, and a drain connected to a gate of a power semiconductor device Q, and the second transistor TR2 may have a source connected to a ground, a gate having a second driving signal applied thereto, and a drain connected to the gate of the power semiconductor device Q, as illustrated in FIG. 2.

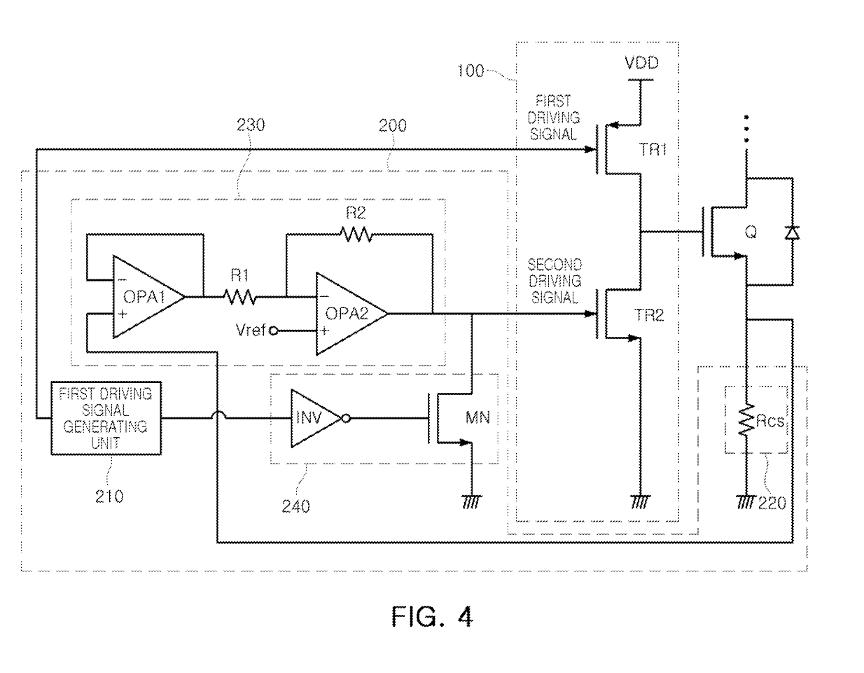

FIG. 3 is a bock diagram illustrating a driving signal generating circuit according to an exemplary embodiment of the present disclosure.

Referring to FIG. 3, the driving signal generating circuit 200 according to the present exemplary embodiment may include a first driving signal generating unit 210, a detecting unit 220, a second driving signal generating unit 230, and a switching unit 240.

The first driving signal generating unit 210 may generate the first driving signal including the high level signal and the low level signal depending on the control signal input from the outside.

The detecting unit 220 may be positioned between the power semiconductor device and a load driven by the power semiconductor device or between the power semiconductor device and a ground and may detect a detection voltage Vcs depending on a current flowing in the power semiconductor device.

The second driving signal generating unit 230 may generate the second driving signal depending on the detection voltage Vcs. For example, the second driving signal generating unit 230 may control a level of the second driving signal to be in inverse proportion to a level of the detection voltage Vcs. That is, the second driving signal generating unit 230 may generate the second driving signal having a low level in the case in which the level of the detection voltage Vcs transferred from the detecting unit 220 is high and generate the second driving signal having a high level in the case in which the level of the detection voltage Vcs is low.

The switching unit 240 may include at least one switch device performing a switching operation by the first driving signal to transfer or block the second driving signal provided from the second driving signal generating unit 230 to the second transistors TR2.

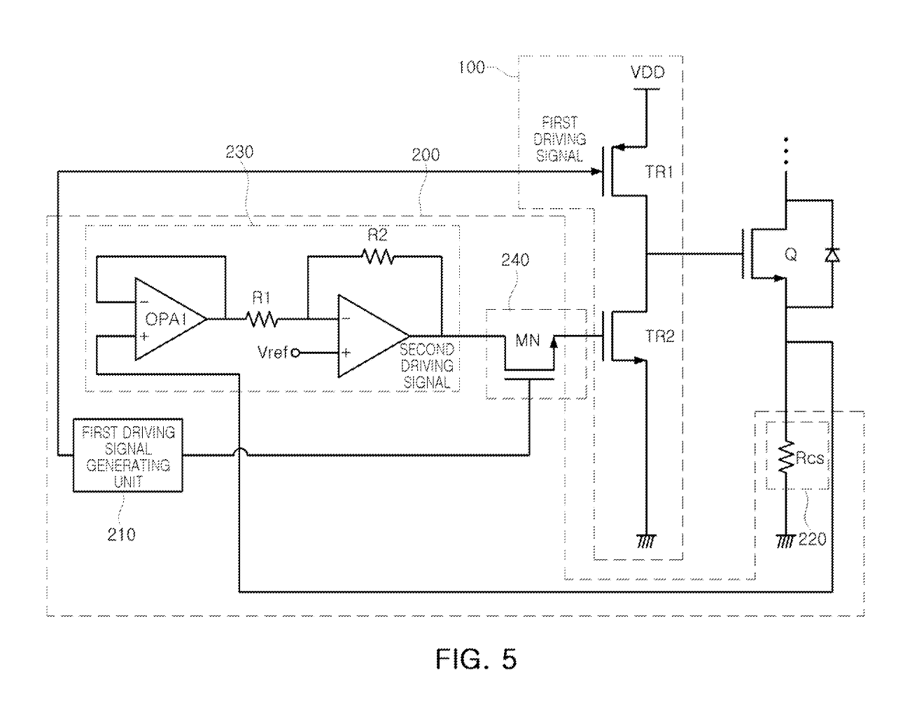

FIGS. 4 and 5 are diagrams illustrating power semiconductor device driving apparatuses according to various exemplary embodiments of the present disclosure. Since examples of the power semiconductor device driving apparatuses illustrated in FIGS. 4 and 5 are only examples illustrating the power semiconductor device driving apparatus illustrated in FIG. 1 in more detail, a description for contents that are the same as or correspond to the above-mentioned contents will be omitted in order to avoid an overlapped description.

Referring to FIG. 4, the driving signal generating circuit 200 according to the present exemplary embodiment may include a first driving signal generating unit 210, a detecting unit 220, a second driving signal generating unit 230, and a switching unit 240.

The first driving signal generating unit 210 may generate a first driving signal including a high level signal or a low level signal and provide the first driving signal to the switching unit 240 and a first transistor TR1.

The detecting unit 220 may include a detection resistor Rcs connected between a power semiconductor device Q and a ground. The detection resistor Rcs may detect a current flowing in the power semiconductor device Q as a detection voltage Vcs. Here, the detection voltage Vcs may be transferred to the second driving signal generating unit 230.

The second driving signal generating unit 230 may include first and second operational amplifier OPA1 and OPA2 and first and second resistors R1 and R2. The first operational amplifier OPA1 may have a non-inverting terminal to which the detection voltage Vcs is applied and an inverting terminal and an output terminal that are connected to each other to serve as a kind of buffer, and an output voltage of the output terminal may be the same as the detection voltage Vcs applied to the non-inverting terminal. The output terminal of the first operational amplifier OPA1 may be connected to one end of the first resistor R1.

The second operational amplifier OPA2 may have a non-inverting terminal to which a reference voltage Vref is applied and an inverting terminal connected to the other end of the first resistor R1. In addition, the inverting terminal and an output terminal of the second operational amplifier OPA2 may be connected to each other through the second resistor R2. Since the inverting terminal and the non-inverting terminal of the second operational amplifier OPA2 maintain the same potential due to a virtual ground, a current I_{R1} flowing in the first resistor R1 may be represented by Mathematical Equation 1.

$${I}_{R 1} = \frac{Vref - Vcs}{R 1} \qquad [ Mathematical Equation 1 ]$$

Since the current I_{R1} flowing in the first resistor R1 flows in the second resistor R2, an output voltage V_{OPA2} of the second operational amplifier OPA2 may be represented by Mathematical Equation 2 and may be used as a second driving signal.

$${V}_{OPA 2} = ( \frac{Vref - Vcs}{R 1} ) * R 2 + Vref \qquad [ Mathematical Equation 2 ]$$

The switching unit 240 may include an inverter INV and a switch MN. The inverter INV may invert the first driving signal provided from the first driving signal generating unit 210 and provide the inverted signal to the switch MN, and the switch MN may perform a switching operation depending on the signal provided from the inverter IVN. As an example, the switch MN may be implemented by an N-channel field effect transistor having a gate connected to an output terminal of the inverter INV, a source connected to a ground, and a drain connected to the output terminal of the second operational amplifier OPA2.

Referring to FIG. 4, in the case in which the low level signal is generated by the first driving signal generating unit 210, the first transistor TR1 is turned on, such that a driving voltage VDD may be applied to a gate of the power semiconductor device Q. Therefore, the power semiconductor device Q may be turned on. In addition, the low level signal generated by the first driving signal generating unit 210 may be inverted into a high level signal by the inverter INV, and the switch MN may be turned on by the signal output from the inverter INV. In the case in which the switch MN is turned on, a gate of the second transistor TR2 may be connected to the ground, such that the second transistor TR2 may be turned off.

To the contrary, in the case in which the high level signal is generated by the first driving signal generating unit 210, the first transistor TR1 may be turned off. In this case, the switch MN is turned off, such that the second transistor TR2 may be turned on by the output voltage V_{OPA2} of the second operational amplifier OPA2. Therefore, the power semiconductor device Q may be turned off.

Referring to FIG. 5, it may be confirmed that a configuration and a connection relationship of a switching unit 240 are partially different from those of the switching unit 240 of FIG. 4. The switching unit 240 of FIG. 5 may include a switch MN. The switch MN may be disposed between the output terminal of the second operational amplifier OPA2 and the gate of the second transistor TR2.

Referring to FIG. 5, in the case in which the low level signal is generated by the first driving signal generating unit 210, the first transistor TR1 is turned on, such that a driving voltage VDD may be applied to a gate of the power semiconductor device Q. Therefore, the power semiconductor device Q may be turned on. In addition, the switch MN may be turned off by the low level signal generated by the first driving signal generating unit 210. In the case in which the switch MN is turned off, the gate of the second transistor TR2 may be disconnected from the output terminal of the second operational amplifier OPA2, such that the second transistor TR2 may be turned off.

To the contrary, in the case in which the high level signal is generated by the first driving signal generating unit 210, the first transistor TR1 may be turned off. In this case, the switch MN is turned on, such that the second transistor TR2 may be turned on by the output voltage V_{OPA2} of the second operational amplifier OPA2.

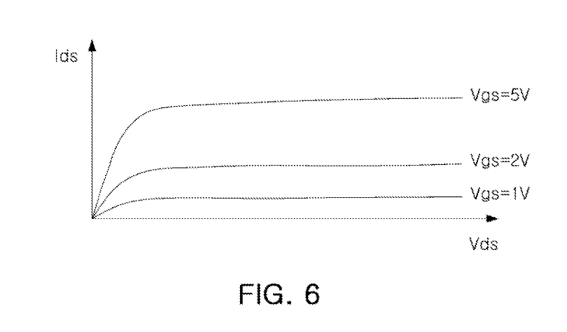

FIG. 6 is a graph illustrating current-voltage characteristics of an N-channel field effect transistor. Referring to FIG. 6, it may be appreciated that as a gate-source voltage Vgs of the N-channel field effect transistor becomes small, a drain-source current Ids thereof becomes small.

Referring to Mathematical Equation 2, as the current flowing in the power semiconductor device Q becomes large, the voltage Vcs detected in the detection resistor Rcs may become large. Therefore, the output voltage of the second operational amplifier OPA2 may become small, such that a time required for turning off the power semiconductor device Q through the second transistor TR2 may be increased.

According to an exemplary embodiment of the present disclosure, the time required for turning off the power semiconductor device is controlled depending on the level of the current flowing in the power semiconductor device, whereby damage to the power semiconductor device may be prevented. In more detail, in the case in which the level of the current flowing in the power semiconductor device is high, the time in which the power semiconductor device is turned off is increased, whereby application of a peak voltage across the power semiconductor device may be prevented.

As set forth, according to exemplary embodiments of the present disclosure, the level of the driving signal is controlled to be in inverse proportion to a level of the current flowing in the power semiconductor device, whereby damage to the power semiconductor device may be prevented.

While exemplary embodiments have been shown and described above, it will be apparent to those skilled in the art that modifications and variations could be made without departing from the spirit and scope of the present disclosure as defined by the appended claims.

What is claimed is:

1. A driving signal generating circuit for generating driving signals provided to first and second transistors driving a power semiconductor device, comprising:
a first driving signal generating unit generating a first driving signal including a high level signal and a low level signal and providing the first driving signal to a gate of the first transistor;
a detecting unit detecting a detection voltage depending on a current flowing in the power semiconductor device;
a second driving signal generating unit generating a second driving signal in inverse proportion to the detection voltage; and
a switching unit performing a switching operation depending on the first driving signal to transfer the second driving signal to a gate of the second transistor.

2. The driving signal generating circuit of claim 1, wherein the detecting unit includes a detection resistor disposed between the power semiconductor device and a ground.

3. The driving signal generating circuit of claim 1, wherein the second driving signal generating unit includes:
a first operational amplifier having an inverting terminal, a non-inverting terminal to which the detection voltage is applied, and an output terminal connected to the inverting terminal;
a first resistor having one end connected to the output terminal of the first operational amplifier;
a second operational amplifier having a non-inverting terminal to which a predetermined reference voltage is applied, an inverting terminal connected to the other end of the first resistor, and an output terminal outputting the second driving signal; and
a second resistor disposed between the inverting terminal of the second operational amplifier and the output terminal of the second operational amplifier.

4. The driving signal generating circuit of claim 1, wherein the switching unit includes:
an inverter inverting the first driving signal; and
a switch performing a switching operation through an output signal of the inverter and disposed between the second driving signal generating unit and a ground.

5. The driving signal generating circuit of claim 1, wherein the switching unit includes a switch disposed between the second driving signal generating unit and the gate of the second transistor.

6. A power semiconductor device driving apparatus comprising:
a driving circuit including a first transistor driven so as to turn on a power semiconductor device and a second transistor driven so as to turn off the power semiconductor device; and
a driving signal generating circuit generating a first driving signal driving the first transistor and a second driving signal driving the second transistor,
wherein a level of the second driving signal is in inverse proportion to that of a current flowing in the power semiconductor device.

7. The power semiconductor device driving apparatus of claim 6, wherein the first transistor is disposed between a predetermined driving voltage terminal and a gate of the power semiconductor device, and the second transistor is disposed between a ground and the gate of the power semiconductor device.

8. The power semiconductor device driving apparatus of claim 6, wherein the first transistor is a P-type transistor, and the second transistor is an N-type transistor.

9. The power semiconductor device driving apparatus of claim 6, wherein the driving signal generating circuit includes:
a first driving signal generating unit generating the first driving signal including a high level signal and a low level signal;
a detecting unit detecting a detection voltage depending on the current flowing in the power semiconductor device;
a second driving signal generating unit generating the second driving signal in inverse proportion to the detection voltage; and
a switching unit performing a switching operation depending on the first driving signal to transfer the second driving signal to a gate of the second transistor.

10. The power semiconductor device driving apparatus of claim 9, wherein the detecting unit includes a detection resistor disposed between the power semiconductor device and a ground.

11. The power semiconductor device driving apparatus of claim 9, wherein the second driving signal generating unit includes:
a first operational amplifier having an inverting terminal, a non-inverting terminal to which the detection voltage is applied, and an output terminal connected to the inverting terminal;
a first resistor having one end connected to the output terminal of the first operational amplifier;
a second operational amplifier having a non-inverting terminal to which a predetermined reference voltage is applied, an inverting terminal connected to the other end of the first resistor, and an output terminal outputting the second driving signal; and
a second resistor disposed between the inverting terminal of the second operational amplifier and the output terminal of the second operational amplifier.

12. The power semiconductor device driving apparatus of claim 9, wherein the switching unit includes:
an inverter inverting the first driving signal; and
a switch performing a switching operation through an output signal of the inverter.

13. The power semiconductor device driving apparatus of claim 9, wherein the switching unit includes a switch disposed between the second driving signal generating unit and the gate of the second transistor.
